(19) United States
(12) Patent Application Publication
(10) Pub. No.: US 2020/0326607 A1
(43) Pub. Date: Oct. 15, 2020

(54) DIELECTRIC TRAVELLING WAVE TIME DOMAIN BEAMFORMER

(71) Applicant: AMI Research & Development, LLC, Merrimack, NH (US)

(72) Inventors: John T. Apostolos, Lyndeborough, NH (US); William B. Mouyos, Windham, NH (US); James Logan, Candia, NH (US)

(21) Appl. No.: 16/779,965

(22) Filed: Feb. 3, 2020

Related U.S. Application Data
(63) Continuation-in-part of application No. 16/746,311, filed on Jan. 17, 2020.
Application No. 16/746,311 is a continuation of application No. 15/615,103, filed on Jun. 6, 2017, now Pat. No. 10,539,856.
Application No. 15/615,103 is a continuation-in-part of application No. 15/887,023, filed on Feb. 2, 2018.
(60) Provisional application No. 62/800,594, filed on Feb. 4, 2019.

(51) Int. Cl. G02F 1/295; G01S 7/481; H01P 3/16; G02B 26/08; G02B 6/42; H01L 31/054; G02B 26/00; G01S 17/42; H04N 5/232

(52) U.S. Cl. CPC G02F 1/295; G01S 7/4817; H01P 3/16; G02B 26/0891; G02B 6/4298; G02B 6/0036; G02B 26/001; G01S 17/42; G01S 7/4816; H04N 5/23245; H01L 31/0543

(57) ABSTRACT

A scanning Dielectric Travelling Wave Array (DTWA) device suitable for use as a wideband, tunable, two-dimensional beamformer. The device is formed from a set of planar waveguides, elongated waveguide sections and/or progressive delay layers. By controlling the index of refraction (ε) of the waveguides, waveguide sections, and/or progressive delay layers, the device to aim at a particular angle of incidence of energy arriving on the top face, in both azimuth and elevation. These indi(cies) of refraction may be controlled with a set of varactors. By observing a constraint on the size of the waveguides as related to the bandwidth of the signals of interest, the waveguide can to receive from or transmit to different directions at the same time. The varactors may be provided by continuous strips of material disposed along the top and bottom of each waveguide section, or as a set of discrete controllable sections distributed along the primary axis of each waveguide section. Pairs of adjacent waveguide sections may be fed to provide complementary propagation modes, such as TE1 and TM1 modes. The pair of waveguide sections may be driven in quadrature to provide greater control over the axial ratio.

### CROSS REFERENCE TO RELATED APPLICATIONS

This application claims priority to a co-pending U.S. Provisional Patent Application Ser. No. 62/800,594 filed Feb. 4, 2019 entitled ‘Dielectric Travelling Wave Time Domain Beamformer” (Attorney Docket No. 111052-0104R) and is a continuation-in-part of a co-pending U.S. patent application Ser. No. 16/746,311 filed Jan. 17,2020 (Attorney Docket No. 111052-0077C1) entitled “Scanning Device”, which is a continuation of issued U.S. Pat. No. 10,539,856 application Ser. No. 15/615,103 filed Jun. 6, 2017 (Attorney Docket No. 111052-0077U) entitled “Scanning Device”, and is further a continuation in part of a co-pending U.S. patent application Ser. No. 15/887,023 filed Feb. 2, 2018 (Attorney Docket No. 111053-0088U) entitled “Dielectric Travelling Waveguide with Varactors to Control Beam Direction”. The entire contents of each these patents and patent applications are hereby incorporated by reference.

### BACKGROUND

Recent developments in the use of dielectric waveguides provide functions normally associated with antenna arrays. The waveguides are generally configured as an elongated slab with a top surface, a bottom surface, a feed end, and a load end. The slab may be formed from two or more dielectric material layers such as silicon nitride, silicon dioxide, magnesium fluoride, titanium dioxide or other materials suitable for propagation at a desired frequency or wavelength of operation.

In one implementation, physical gaps are formed between the layers. A control element is also provided to adjust a size of the gaps. The control element may, for example, be a piezoelectric or electroactive material or a mechanical position control. Changing the size of the gaps allows for controlling the effective propagation constant. In another implementation, a series of solid state devices, such as varactors, can provide the same effect—to control the effective propagation constant of the waveguide. Either approach in turn allows for scanning a resulting radiation beam at different angles. These devices have been designed for use at radio frequencies, acting as a directional radio antenna, and at visible or solar wavelengths.

As explained in the above referenced U.S. Pat. No. 10,539,856, a coupling layer may also be used that has a dielectric constant that changes as a function of distance from the excitation end to the load end. By providing increased coupling between the waveguide and the correction layer in this way, horizontal and vertical mode propagation velocities may be controlled.

Also, adjacent dielectric layers may be formed of materials with different propagation constants. In those implementations, layers of low dielectric constant material may be alternated with layers of high dielectric constant material. These configurations can provide frequency-independent control over beam shape and beam angle.

U.S. patent application Ser. No. 15/877,023 mentioned above (and published as U.S. Patent Publication 2018/0226714A1) further shows a type of adjustable dielectric travelling wave arrangement that provides a steerable beam without the need for physically movable gaps between the layers. Instead, one or more varactors provide control over the impedance of a waveguide section disposed between two or more layers. The effective propagation constant of the waveguide may then be controlled by changing the voltage on the varactors.

### SUMMARY

The apparatus described herein is a type of dielectric travelling waveguide array (DTWA) device that can be used to steer radiation in two dimensions. The device tunable and rapidly switchable over a broad band of frequencies, and therefore is particularly suited for use as a receiver or transmitter in emerging communication networks.

In a preferred implementation, the device includes a first or main unitary continuous waveguide that may be square in shape to provide a square aperture to energy in both an azimuth an elevation plane. A progressive delay layer is placed on the top surface. A second or auxiliary progressive delay layer and waveguide are disposed adjacent an exit face of the main waveguide. The delay introduced by these layers is preferably a continuous, linear propagation delay. The delays layers may be implemented as a flat layer of material with a particular shape or construction. Radio frequency detector(s) are disposed adjacent an exit face of the auxiliary waveguide.

By controlling the index of refraction (ε) of the waveguides and/or progressive delay layers, one can in turn cause the device to aim at a particular angle of incidence of energy arriving on the top face, in both azimuth and elevation, and thus aim the detector(s). In a solid state implementation, these indi(cies) of refraction may be controlled with a set of varactors that control the impedance of a propagation path disposed between two or more waveguide layers.

By observing a particular constraint on the size of the waveguides as related to the bandwidth of the signals of interest, it is possible to rapidly sample different beams sequentially, to receive from or transmit to different directions at the same time. In particular, for a square waveguide having an aperture of length X by X, sufficient time may be provided to collect energy travelling along a longest possible diagonal path, to maximize signal gain at the detector (and/or emitter). In one example, if 2X is about 1 ns, then the spatial Nyquist switching rate can be on the order of 500 MHz. Thus, such a device is able to validly process signals arriving from multiple directions as long as the one-half of the reciprocal of their combined bandwidth is smaller than about twice the maximum transit time through the waveguide. The device can therefore serve to receive multiple signals at the same time, or as a Multipe Input Multiple Output (MIMO) receiver for a given signal.

For one implementation, a set of linear waveguide sections disposed in parallel with one another may be used instead of a unitary main waveguide.

In such an arrangement, the varactors may be provided by continuous strips of material disposed along the top and bottom of each waveguide section. However, in other arrangements, the varactors may be implemented as a set of discrete controllable sections distributed along the primary axis of each waveguide section. The latter approach, which results in a two-dimensional array of varactors, provides greater efficiency, as it permits a phase progression to be implemented along both axes of the device.

In still other arrangements, pairs of adjacent waveguide sections may be fed to provide complementary propagation modes, such as TE1 and TM1 modes. The pair of waveguide sections are driven in quadrature to provide greater control over the axial ratio. In this arrangement, the dispersion of the TE1 and TM1 modes should be selected to match as much as possible.

In operation of any of these embodiments, the state of the varactors are controlled to steer the beam, enabling rapid, time domain beamforming over a broad bandwidth of at least 3:1.

### BRIEF DESCRIPTION OF THE DRAWINGS

The following description of preferred embodiments should be read together with the accompanying drawings, of which:

FIG. 1 is an isometric view of one implementation of the device.

FIG. 2 illustrates a solid-state implementation using varactors to control an angle of incidence of the device.

FIG. 3 shows an incident wave at an angle of maximum distance to a focal point at a detector within the device.

FIG. 4 is another implementation where each waveguide section includes a set of varactors.

FIG. 5 is a cut away view showing the varactors of FIG. 4 in more detail.

FIG. 6 shows multiple simultaneous incident waves.

FIG. 7 shows another implementation with pairs of adjacent waveguide sections forming matched quadrature pairs.

FIG. 8 is a more detailed view of a matched TE1 and TM1 mode pair.

FIG. 9 is another implementation where the wedge layer is replaced with a flat layer having a series of varactors.is another embodiment that uses solid state varactors in place of the wedge layer and/or wedge attributes incorporated into the solid state waveguide.

### DETAILED DESCRIPTION

Described herein are waveguide structures adapted for scanning at radio frequencies. Particular implementations use an auxiliary progressive delay with waveguide structure configuration to feed a main progressive delay with waveguide structure to scan in two dimensions (2D), such as azimuth and elevation, over a broad bandwidth of at least 3:1.

(Add a Drawing from 0077) Here).

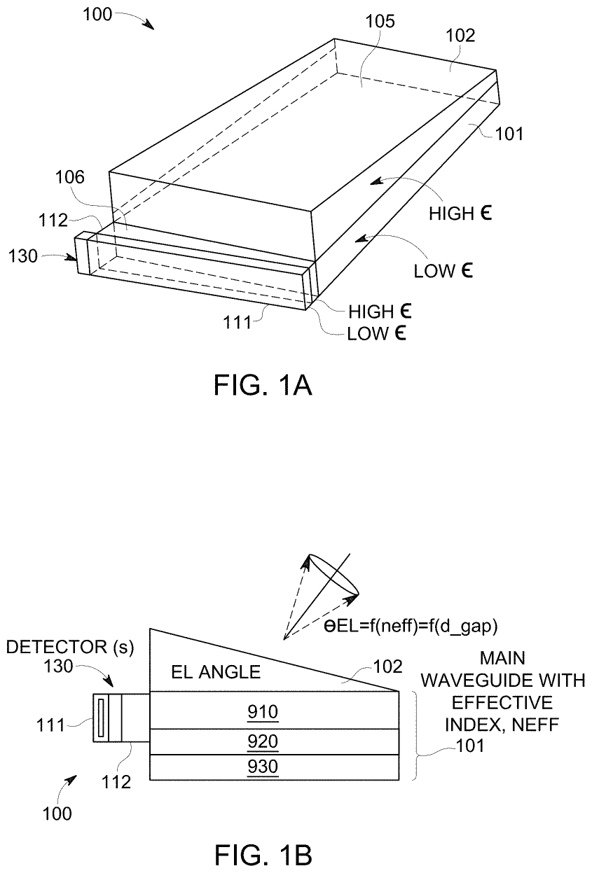

FIG. 1A is a perspective view of one such implementation where a steerable “element-less” Dielectric Travelling Wave Antenna (DTWA) device 100 is provided by a main rectangular waveguide structure 101. The waveguide 101 is generally rectangular, and often square shaped with a dimension of X by X. The waveguide includes a top surface 105 and exit face 106. Typical dielectric materials for the waveguide may include silicon nitride, silicon dioxide, magnesium fluoride, titanium dioxide or other materials suitable for propagation at a desired operating wavelength.

A main progressive delay layer 102 is preferable placed on the top surface 105 of waveguide 101. A second or auxiliary waveguide 111 and progressive delay layer 112 are disposed adjacent the exit face 106 of the main waveguide 101. The delay introduced by layers 102,112 is preferably a continuous, linear propagation delay. The layers may be implemented as a layer of material with a particular shape or in other ways as will be described below. The delay(s) can also incorporate a taper to provide side lobe suppression, such as a tailor or cosine distribution.

When the device 100 operates as a receiver, one or more RF energy detectors 130 are disposed adjacent an exit face of the auxiliary waveguide 111. The detector may be broadband, or may be provided by multiple narrower band detectors. When the device operates as a transmitter, RF energy source is used in place of the detectors 130.

By controlling the index of refraction (ε) of the waveguides 101, 111 and/or progressive delay layers 102, 112=one can in turn control an angle of incidence of energy arriving on the top face and hence on the detector(s) 30. Note also that the index of refraction (ε_{low}) of the main waveguide 101 is typically lower than the index of refraction (ε_{high}) of the delay layer 102.

The main delay structure 102 provides progressive delay excitation to facilitate scanning in the elevation direction. The auxiliary structure 112 provides progressive delay excitation to effect scanning in the azimuthal direction. The resulting device can thus scan in both theta and phi (for example, elevation and azimuth) without the need for multiple detectors, or mechanical scanning apparatus.

Other details of the implementation are described in the above-referenced co-pending patent application that was incorporated by reference.

The beam direction in a continuous waveguide with a progressive delay layer is affected by dispersion in the waveguide and the progressive delay layer. Rather than eliminating the dispersion for each component, it is possible to match the dispersions in the waveguide and progressive delay layer. Again, see the referenced patent application for more details.

In a preferred embodiment, the propagation constant of the main waveguide 101 is controlled using a set of fixed, solid state structures such, but not limited to, varactors. It should be understood that the auxiliary waveguide 111 placed adjacent the exit face of main waveguide 101 may be similarly constructed with a set of varactors.

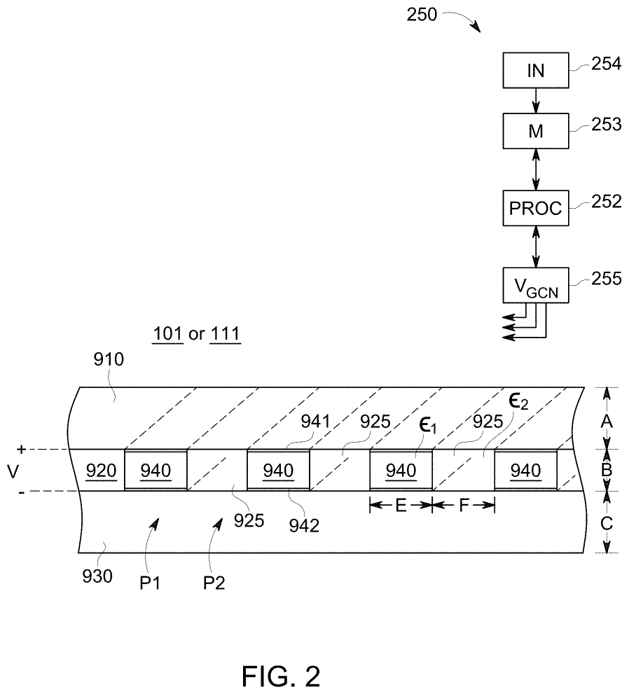

As shown in FIG. 1B amd also in FIG. 2, waveguide 101 (and similarly or auxiliary waveguide 111) may comprise three layers, including an upper waveguide layer 910, middle layer 920, and lower waveguide layer 930. Middle layer 920, also called the varactor layer herein, is formed of alternating sections 925, 940 of different materials having different respective dielectric propagation constants. An example first section 940 is formed of a first dielectric material having the same, or nearly the same, propagation constant ε₁, as layers 910, 930. An example second section 925 is formed of a second dielectric having a different propagation constant ε₂ than the first section 940.

Thus layers 910, 930 and sections 940 may have a first propagation constant ε₁, and sections 925 may have a second propagation constant of ε₂. In one implementation, ε₁ is 36 and ε₂ is 2; that is, ε₁ is much greater than ε₂.

A material such as Indium Tin Oxide (ITO) may be deposited on the top and bottom of sections 940 such as at 941, 942 to provide a varactor. A voltage generator, also referred to as a control circuit herein (not shown in FIG. 2) imposes a controllable voltage difference, V, across 941, 942.

It should also be understood that conductive traces are deposited on or within one or more of the ITO layers to connect the varactors to a control circuit 250 that controls the state of each individual varactor. The control circuit 250 may include a processor 252, memory 253, input device 254 and voltage generator(s) 255 which may be digital to analog converters. The processor 252 may, in response to input received at 254, execute instructions sotred in the memory 253 to generate the set of voltages to control the varactor sections 940. Although not shown in the drawings, it is also understood that the controller 250 my include fixed logic, a field programmable gate array, programmable microcontroller, amplifiers, switches, capacitors, etc. that provide a circuit capable of setting and maintaining the multiple voltages and/or states of the varactors and/or sections 940.

The control voltages applied to the varactors thus changes the impedance of paths, P₁, from the upper waveguide 910, through each of the dielectric section(s) 940 to the lower waveguide 930. When that control voltage is relatively high, the dielectric sections 940 become more connected to the adjacent layers 910, 930—that is, the impedance through path P₁ is relatively lower than the impedance through path P₂. When that voltage difference is relatively smaller, the impedance through path P₁ becomes relatively higher. Changing the control voltage on each varactor thus changes the overall propagation constant of the waveguide 100 at that location. The voltages can thus be used to steer the resulting beam.

In some implementations, there may be further control over the voltages applied to different ones of the sections 940 to provide a different impedance of the waveguide structure as a function of horizontal distance. That approach can provide the same properties as the implementation that has a dimensional wedge or taper layer as in the implementation of FIG. 1A.

For example, if the impedance through path P₁ is given by zi and the impedance through path P₁ by z₂, and those impedances are progressively changed as a function of distance along the waveguide, the relative propagation constant βo can be shown to be a function of z as follows:

$${β}_{o} = \sqrt{\frac{z 1}{z 2}}$$

with the impedance, z, of a particular varactor section 940 may depend upon a ratio of its width and height.

To provide progressive delay along the waveguide, the impedance z of a particular waveguide section may be changed as a function of its position or distance, x, along the waveguide, such that z₁=z₁(x) and z₂=z₂(x). In this way, one can effect a delay to incident energy arriving at the waveguide depending upon location along the waveguide. This provides the analogous result as the implementation of FIG. 1 that uses wedge shaped physical layers 102, 112.

One can also control the amount of dispersion in the waveguide 100 by controlling the spacing F between the varactor sections 940. Spacing them at a fraction of the operating wavelength (λ) of about λ/10 apart appears to be preferable, although λ/4 would provide more dispersion.

Other variations are possible as described in the referenced co-pending patent application. For example, the main waveguide 101 or auxiliary waveguide 111 may have more than three layers with progressively larger thickness, although implementations with multiple layers with uniform thickness is also possible. The relative increase in thickness can follow a proscribed pattern, such as a chirped or Bragg pattern, as also described in the patents and patent applications referenced above. The device 100 can be used to receive and/or transmit radio frequency (RF) by coupling to antenna arrays of different types. For example, device 100 may be used to feed one of the Orientation Independent Antennas described in U.S. Pat. Nos. 8,988,303 and 9,013,360 as well as U.S. patent application Ser. No. 15/362,988 filed Nov. 29.

As also described in the above-referenced patent application, waveguide 101 or 111 is formed of two facing layers of a material such as zinc oxide (ZnO). A magnesium fluoride (MgF₂) layer is formed on each facing surface such as by sputter deposition on the two facing ZnO layers. Conductive fingers are deposited on the facing surfaces to form interdigital transducers. By driving the two transducers with opposite phases (+ and − sine waves, for example, at 1 GHz), a standing acoustic wave may be produced along the facing surfaces. Changing the frequency or the shape of the driving signal can also thus change the propagation constant of the waveguide.

As mentioned above briefly, the device 100 can be used in a time domain beamforming mode. In particular, since the 100 has an inherently wide bandwidth, it is possible to generate different beams sequentially and preferably rapidly in time, to receive signals arriving from different directions.

The speed of the time-multiplexed generation of beams is limited by the interaction time of the device 100 with signals of interest. The interaction time is, in turn, determined by the size of the device and the bandwidth of the signal.

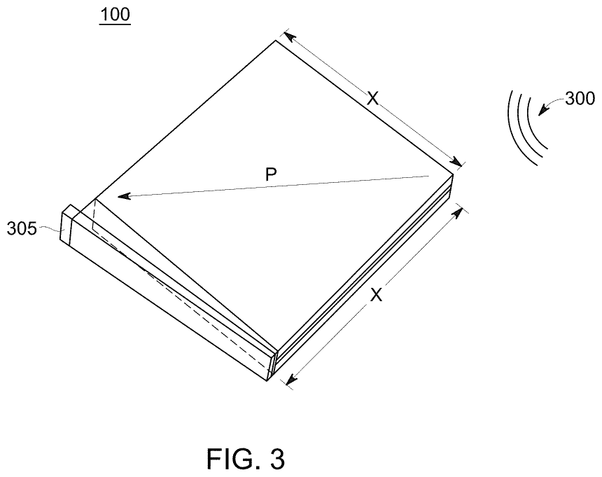

With particular reference to FIG. 3, in such an application, the waveguide 300 must be fully illuminated to capture incident signals arriving from any or all directions. Thus, any time switching of beams must be controlled at a speed sufficient capture a signal 300 propagating from the direction opposite where the detectors 305 are located (e.g., opposite a “focal point”). For a waveguide having an aperture of X by X, energy received from an incident wave 300 that travels through path P (along the longest possible diagonal path) must be permitted sufficient time to traverse the entire waveguide, e.g., a time of approximately 1.41X, if we are to maximize signal gain at the detector.

To leave a margin of safety, any beam switching of the device 100 might be somewhat slower and thus limited to about one-half of the reciprocal of the transit time of 2X. If in one example, 2X is about 1 ns, then the spatial Nyquist rate is on the order of 500 MHz. Thus, for signal bandwidth of less than 500 MHz, is possible with such a device to validly sample one or more signals of interest by switching the array beam at the temporal Nyquist rate associated with the signal of interest. Consider an example use case for a Low Earth Orbiting (LEO) satellite system operating in the Ku band. The bandwidth of a signal in such a system might be 12.5 MHz. Such a DTWA 100 would be able to generate 50 simultaneous beams to validly service 40 or possibly even 50 signals of interest.

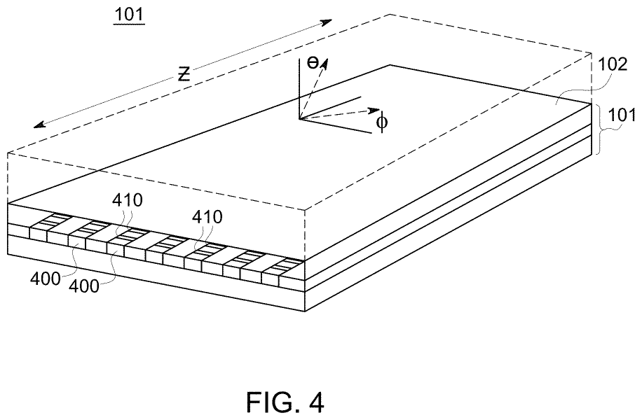

FIG. 4 illustrates an alternate embodiment a DTWA device 100. Here the continuous waveguide 100 of FIGS. 1A and 1B is replaced with a set of linear waveguide sections 400 that provide improved axial ratio control (e.g., for circular polarization) over 2π steradians. This element-less structure does not require discrete individual antenna elements, and yet still provides time domain beam steering, functioning similar to how an array of radiating elements might be operated.

The implementations of the device 100 such as shown in FIG. 1A or FIG. 3 include varactors provided by continuous strips of material extending along the top and bottom of each waveguide section. The implementation of FIG. 4 differs, however, in that each waveguide section 400 itself now contains a series of discrete solid-state varactors 410. This series of discrete controllable sections 410, distributed along the primary axis of each waveguide section, results in a two-dimensional array of varactors. The two-dimensional array provides greater overall efficiency of the device 100, as it now permits a phase progression to be implemented along both axes θ and φ of the device 100.

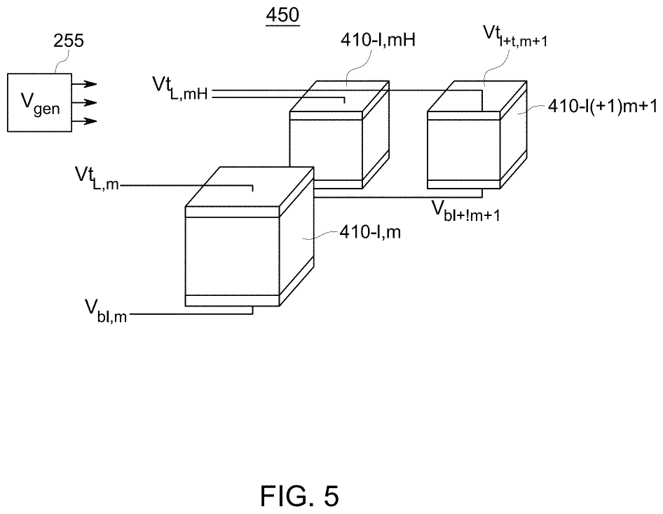

FIG. 5 is another, cut away view of the implementation of FIG. 4 showing a portion of the array 450 of varactors with the rest of the waveguide 101 not shown for clarity. Voltage generator 455 provides varactor 410_{l,m} with a voltage Vt_{l,m} at its top layer and voltage Vb_{l,m} at its bottom layer. Similarly, varactor 410_{l,m+1} receives voltage Vt_{l,m+1} at its top layer and voltage Vb_{l,m+1} at its bottom layer. Varactor 410_{l+1,m+1} receives voltage Vt_{l+1,m+1} at its top layer and voltage Vb_{l+1,m+1} at its bottom layer.

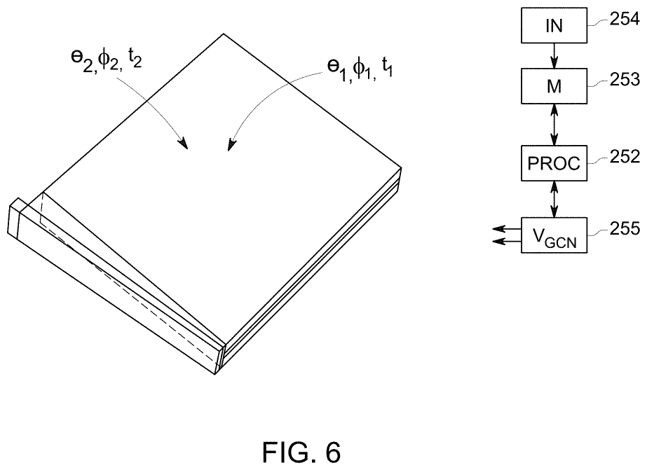

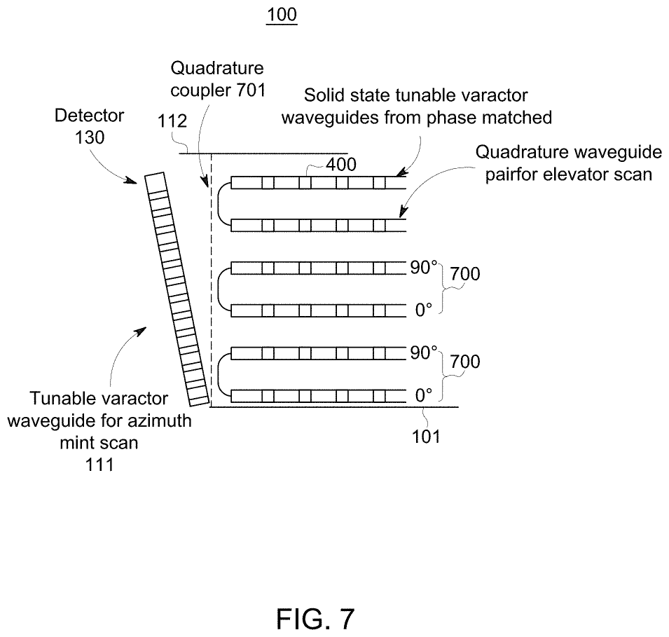

FIG. 6 illustrates how the device 100 of FIG. 1A, 3, or 4 (or FIG. 7, as discussed below) can be used to receive multiple signals at the same time from multiple directions. For example, at time t1, the varactors can be activated by the controller 250 to aim the device in a direction ϕ₁, θ₁ and at time t2, the varactors can be set to aim the device in a second direction ϕ₂, θ₂. Switching between the two directions may occur as fast as that dictated by the propagation time through the waveguide, as discussed above.

In still other arrangements, as shown in FIG. 7, pairs 700 of adjacent waveguide sections 410 may be fed to provide complementary propagation modes. The complimentary propagation modes may include TE1 and TM1 modes. Each pair of waveguide sections 700 is driven by a respective quadrature coupler 701 to provide greater control over the axial ratio. In this arrangement, the dispersion of the TE1 and TM1 modes should be selected to match as much as possible.

As with the arrangement of FIGS. 1A, 3 and 4, the version of the device 100 shown in FIG. 7 can be steered in both azimuth and elevation by selectively controlling the voltages applied to the varactors, to effect a change in the propagation constant of the individual waveguide sections.

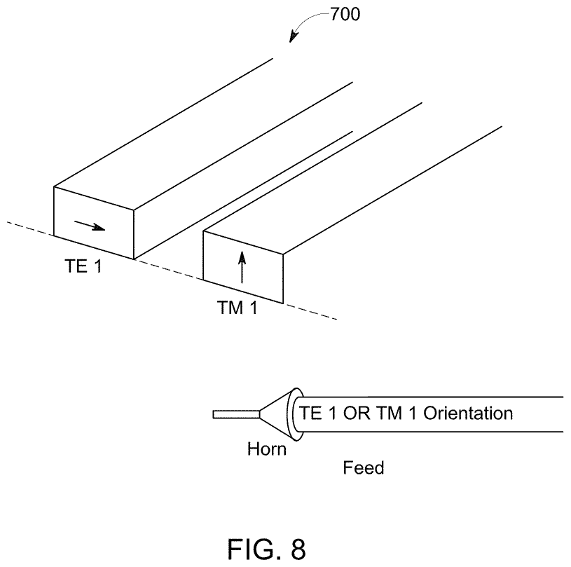

As shown in FIG. 8, one of each waveguide pair 700 is coupled to operate in the transverse electric (TE₁) mode, and another of the pair 700 is operated the transverse magnetic (TM₁) mode. The TE₁ and TM₁ mode sections should have matching dispersion characteristics for optimum performance. The respective transverse mode, either the TE₁ or TM₁ mode for a given waveguide section, may be determined by which edge of the waveguide is coupled. When also phase matched, these quadrature waveguide pairs 700 provide both the desired variable dielectric function and a progressive delay function. The quadrature coupled TE₁ and TM₁ mode waveguide sections permit greater control over the axial ratio of the device 400 within a field of regard.

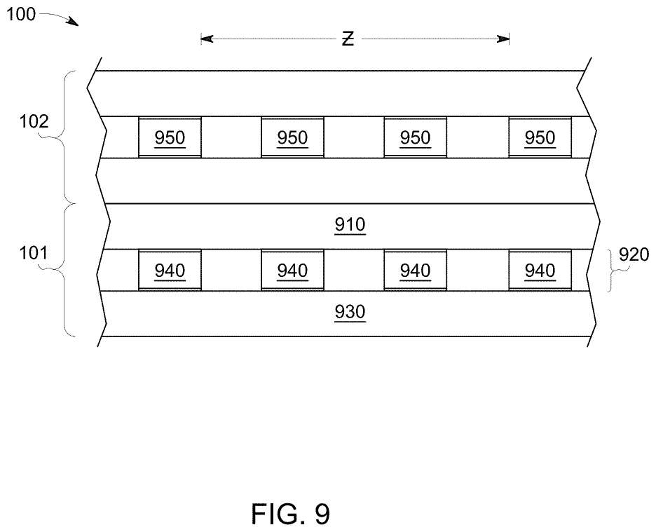

FIG. 9 is another arrangement where the wedge shaped delay layer 102 is replaced with a flat waveguide layer having a series of controllable varactors 950 that provide a propagation constant that varies as a function of distance, Z, along the top face of waveguide 101. The same result is provided, progressive delay, but within a flat form factor. Here the solid state varactors 950 function in place of the wedge layer such that wedge attributes are incorporated into the solid state waveguide. It should be understood that a similar flat delay layer 112 may be provided adjacent the auxiliary waveguide 111.

The DTWA device 100 described herein, providing steerable beams and controllable axial ratio, can now be used in communication systems where a broadband tunable receiver is needed. For example, efficiencies across a 3:1 frequency band can be expected to be similar to those reported in U.S. Pat. No. 9,281,424 incorporated by reference (noting in particular FIG. 4B and the related discussion therein).

The above description contains several example embodiments. It should be understood that while a particular feature may have been disclosed above with respect to only one of several embodiments, that particular feature may be combined with one or more other features of the other embodiments as may be desired and advantageous for any given or particular application. It is, of course, not possible to describe every conceivable combination of components or methodologies for purposes of describing the innovations herein, and one skill in the art may now, in light of the above description, recognize that many further combinations and permutations are possible.

Accordingly, the claimed subject matter is intended to embrace all such alterations, modifications, and variations that fall within the spirit and scope of the appended claims. Furthermore, to the extent that the terms “includes,” and “including” and variants thereof are used in either the detailed description or the claims, these terms are intended to be inclusive in a manner similar to the term “comprising”.

1. A scanning apparatus comprising:
a main waveguide structure having a top surface and exit face, and having an azimuth aperture of a first dimension along a first axis and an elevation aperture of a second dimension along a second axis, presenting a maximum transit time that depends on the first and second dimensions;
a main progressive delay layer disposed adjacent the top surface of the main waveguide;
a second waveguide and second progressive delay layer disposed adjacent the exit face of the main waveguide, the second waveguide also having a top surface and an exit face;
wherein an index of refraction (ε) of the waveguides and/or progressive delay layers are arranged to be adjustable to control a beam direction; and
a controller, for changing the index of refraction of the waveguides and/or progressive delay layers over time, to switch between a first beam direction and a second beam direction over time, at a rate sufficient to validity detect energy arriving from both the first and second beam direction.

2. The apparatus of claim 1 wherein the energy arriving from the first beam direction and second beam direction originates from two respective different sources.

3. The apparatus of claim 1 wherein the energy arriving from the first beam direction and second beam direction originate from a given source.

4. The apparatus of claim 1 wherein the main waveguide structure further comprises:
a first dielectric layer and a second dielectric layer;
a third dielectric layer disposed between the first and second dielectric layers, and the third layer comprises a plurality of alternating elongated sections formed of dielectric material, with adjacent ones of the alternating elongated sections having different propagation constants, and
with a selected subset of the elongated sections each having two or more varactors disposed along the length thereof.

5. The apparatus of claim 4 where each varactor further comprises:
a section of semiconductor material having a rectangular cross section and having a top face and a bottom face opposite the top face;
a first conductive section disposed adjacent the top face; and
a second conductive section disposed adjacent the bottom face.

6. The apparatus of claim 5 wherein the controller additionally provides a series of bias voltages to two or more of the varactors formed in a given elongated section.

7. The apparatus of claim 5 wherein the control circuit is further coupled to provide different bias voltages are applied to the two or more varactors associated with adjacent elongated sections.

8. The apparatus of claim 5 wherein a first subset of the elongated subsections is arranged to operate in a TE1 propagation mode, and a second subset of the elongated subsections is arranged to operate in a TM1 propagation mode.

9. The apparatus of claim 8 additionally comprising:
two or more directional couplers, coupled to selected pairs of elongated subsections operating in TE1 mode and TM1 mode.

10. An apparatus comprising:
a dielectric waveguide formed of at least a first layer and a second layer;
a third layer disposed between the first and second layers, and the third layer comprises a plurality of alternating elongated sections formed of dielectric material, with adjacent ones of the alternating elongated sections having different propagation constants, and
with a selected subset of the elongated sections each having two or more varactors disposed along the length thereof.

11. The apparatus of claim 10 where each varactor further comprises:
a section of semiconductor material having a rectangular cross section and having a top face and a bottom face opposite the top face;
a first conductive section disposed adjacent the top face; and
a second conductive section disposed adjacent the bottom face.

12. The apparatus of claim 11 additionally comprising:
is a control circuit, coupled to provide a series of bias voltages to two or more of the varactors formed in a given elongated section.

13. The apparatus of claim 12 wherein the control circuit is further coupled to provide different bias voltages are applied to the two or more varactors associated with adjacent elongated sections.

14. The apparatus of claim 10 wherein a first subset of the elongated subsections is arranged to operate in a TE1 propagation mode, and a second subset of the elongated subsections is arranged to operate in a TM1 propagation mode.

15. The apparatus of claim 14 additionally comprising:
two or more directional couplers, coupled to selected pairs of elongated subsections operating in TE1 mode and TM1 mode.

16. The apparatus of claim 10 additionally comprising:
a progressive delay layer, disposed adjacent the first layer, the progressive delay layer including a series of varactors disposed along an axis thereof.
